(19) United States
(12) Patent Application Publication
(10) Pub. No.: US 2025/0132239 A1
(43) Pub. Date: Apr. 24, 2025

(54) POROUS LINERS FOR THROUGH-GLASS VIAS AND ASSOCIATED METHODS

(71) Applicant: Intel Corporation, Santa Clara, CA (US)

(72) Inventors: Hongxia Feng, Chandler, AZ (US); Thomas Stanley Heaton, Gilbert, AZ (US); Shayan Kaviani, Phoenix, AZ (US); Yonggang Li, Chandler, AZ (US); Mahdi Mohammadighaleni, Phoenix, AZ (US); Bai Nie, Chandler, AZ (US); Dilan Seneviratne, Phoenix, AZ (US); Joshua James Stacey, Chandler, AZ (US); Hiroki Tanaka, Gilbert, AZ (US); Elham Tavakoli, Phoenix, AZ (US); Ehsan Zamani, Phoenix, AZ (US)

(73) Assignee: Intel Corporation, Santa Clara, CA (US)

(21) Appl. No.: 19/005,161

(22) Filed: Dec. 30, 2024

(51) Int. Cl. H01L 23/498

(52) U.S. Cl. CPC H01L 23/49827; H01L 23/49883; H01L 23/49894

(57) ABSTRACT

Porous liners for through-glass vias and associated methods are disclosed. An example apparatus includes a glass layer having a through-hole. The example apparatus further includes a conductive material within the through-hole. The example apparatus also includes a porous material between at least a portion of the conductive material and at least a portion of a sidewall of the through-hole.

### BACKGROUND

In many electronic devices, integrated circuit (IC) chips and/or semiconductor dies are connected to larger circuit boards such as motherboards and/or other types of printed circuit boards (PCBs) via a package substrate. Some package substrates include a glass substrate (e.g., a glass core) having one or more openings extending between first and second sides of the glass substrate. Conductive material may be provided in the openings to electrically couple devices (e.g., the IC chips and/or semiconductor dies) to each other and/or to a PCB.

### BRIEF DESCRIPTION OF THE DRAWINGS

FIG. 1 illustrates an example integrated circuit (IC) package constructed in accordance with teachings disclosed herein.

FIGS. 2-6 illustrate various stages in an example fabrication process of an example glass core that may be used to implement the example glass core of FIG. 1.

FIGS. 7-12 illustrate various stages in another example fabrication process of another example glass core that may be used to implement the example of FIG. 1.

FIG. 13 illustrates another example glass core that may be used to implement the example of FIG. 1.

FIG. 14 illustrates another example glass core that may be used to implement the example of FIG. 1.

FIG. 15 is a flowchart representative of an example method of manufacturing any one of the example glass cores of FIGS. 6 and/or 12-14.

FIG. 16 is a top view of a wafer including dies that may be included in an IC package constructed in accordance with teachings disclosed herein.

FIG. 17 is a cross-sectional side view of an IC device that may be included in an IC package constructed in accordance with teachings disclosed herein.

FIG. 18 is a cross-sectional side view of an IC device assembly that may include an IC package constructed in accordance with teachings disclosed herein.

FIG. 19 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

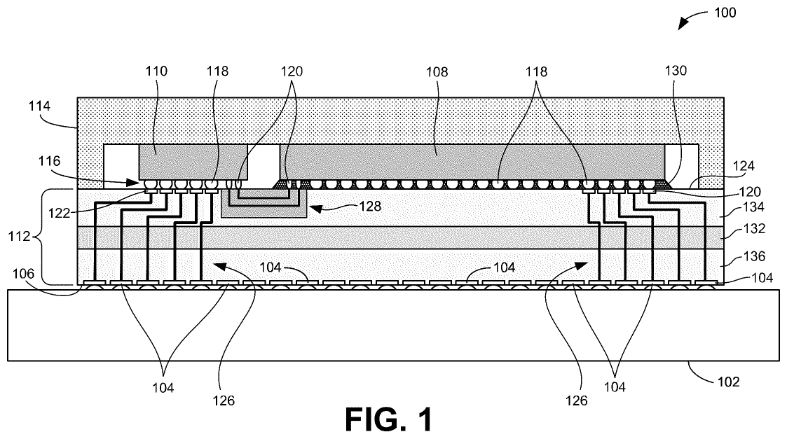

FIG. 1 illustrates an example integrated circuit (IC) package 100 constructed in accordance with teachings disclosed herein. In the illustrated example, the IC package 100 is electrically coupled to an underlying substrate 102 via an array of contacts 104 on a package mounting surface 106 (e.g., a bottom surface, an external surface) of the package. In some examples, the substrate 102 can be implemented by a printed circuit board (PCB) or a package substrate (e.g., the IC package 100 is part of another larger package). In the illustrated example, the contacts 104 are represented as pads or lands. However, in some examples, the IC package 100 may include balls, pins, and/or any other type of contact, in addition to or instead of the pads or lands shown to enable the electrical coupling of the IC package 100 to the substrate 102. In this example, the package 100 includes two semiconductor dies 108, 110 (e.g., silicon dies), sometimes also referred to as chips or chiplets, that are mounted to a package substrate 112 and enclosed by a package lid 114 (e.g., a mold compound, an integrated heat spreader (IHS)). Thus, the package substrate 112 is an example means for supporting a semiconductor die. In some examples, the package lid 114 is omitted, thereby leaving the semiconductor dies 108, 110 exposed or bare.

While the example IC package 100 of FIG. 1 includes two dies 108, 110, in other examples, the IC package 100 may have only one die or more than two dies. In some examples, one of the dies 108, 110 (or a separate die) is embedded in the package substrate 112. The dies 108, 110 can provide any suitable type of functionality (e.g., data processing, memory storage, etc.). In some examples, one or both of the dies 108, 110 are implemented by a die package including multiple dies arranged in a stacked formation. For example, the die 110 can include a stack of Dynamic Random Access Memory (DRAM) die arranged on top of a memory controller die to form a memory die stack.

As shown in the illustrated example, each of the dies 108, 110 is electrically and mechanically coupled to the package substrate 112 via corresponding arrays of interconnects 116. In FIG. 1, the interconnects are shown as bumps. In some examples, the interconnects 116 can include solder joints, micro bumps, combinations of metallic (e.g., copper) pillars and solder, etc. In other examples, the interconnects 116 may include directly bonded or “hybrid bonded” metallic interconnects. In other examples, the interconnects 116 may be any other type of electrical connection in addition to or instead of the bumps shown (e.g., balls, pins, pads, pillars, wire bonding, etc.). The electrical connections between the dies 108, 110 and the package substrate 112 (e.g., the interconnects 116) are sometimes referred to as first level interconnects. By contrast, the electrical connections between the IC package 100 and the substrate 102 (e.g., the contacts 104) are sometimes referred to as second level interconnects. In some examples, one or both of the dies 108, 110 may be stacked on top of one or more other dies and/or an interposer. In such examples, the dies 108, 110 are coupled to the underlying die and/or interposer through a first set of first level interconnects and the underlying die and/or interposer may be connected to the package substrate 112 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 116 of the first level interconnects include two different types of bumps corresponding to core bumps 118 and bridge bumps 120. As used herein, the core bumps 118 are bumps on the dies 108, 110 through which electrical signals pass between the dies 108, 110 and components external to the IC package 100. More particularly, as shown in the illustrated example, when the dies 108, 110 are mounted to the package substrate 112, the core bumps 118 are physically connected and electrically coupled to contact pads 122 on a die mounting surface 124 (e.g., an upper surface, a top surface, etc.) of the package substrate 112. The contact pads 122 on the die mounting surface 124 of the package substrate 112 are electrically coupled to the contacts 104 on the package mounting surface 106 (e.g., the bottom, external surface) of the package substrate 112 (e.g., a surface opposite the die mounting surface 124) via internal interconnects 126 within the package substrate 112. As a result, there is a continuous electrical signal path between the core bumps 118 of the dies 108, 110 and the contacts 104 mounted to the substrate 102 that pass through the contact pads 122 and the interconnects 126 provided therebetween. As shown, the package mounting surface 106 and the die mounting surface 124 define opposing outer surfaces of the package substrate 112. While both surfaces are outer surfaces of the package substrate, the die mounting surface 124 is sometimes referred to herein as an internal or inner surface relative to the overall IC package 100. By contrast, in this example, the package mounting surface 106 is an outer or exterior surface of the IC package 100.

As used herein, the bridge bumps 120 are bumps on the dies 108, 110 through which electrical signals pass between different ones of the dies 108, 110 within the IC package 100. Thus, as shown in the illustrated example, the bridge bumps 120 of the first die 108 are electrically coupled to the bridge bumps 120 of the second die 110 via an interconnect bridge 128 (e.g., a silicon-based interconnect bridge, an interconnect die, an embedded interconnect bridge (EMIB)) embedded in the package substrate 112. As represented in FIG. 1, core bumps 118 are typically larger than bridge bumps 120. In some examples, the interconnect bridge 128 and the associated bridge bumps 120 are omitted.

In some examples, an underfill material 130 is disposed between the dies 108, 110 and the package substrate 112 around and/or between the first level interconnects 116 (e.g., around and/or between the core bumps 118 and/or the bridge bumps 120). In the illustrated example, only the first die 108 is associated with the underfill material 130. However, in other examples, both dies 108, 110 are associated with the underfill material 130. In other examples, the underfill material 130 is omitted. In some examples, the mold compound used for the package lid 114 is used as an underfill material that surrounds the first level interconnects 116.

In some examples, the IC package 100 includes additional passive components, such as surface-mount resistors, capacitors, and/or inductors disposed on the package mounting surface 106 of the package substrate 112 and/or the die mounting surface 124 of the package substrate 112.

In FIG. 1, the substrate 112 of the example IC package 100 includes a glass core 132 (e.g., a glass substrate, a glass layer, etc.) between two separate build-up layers or regions 134, 136 (e.g., a first build-up region 134 and a second build-up region 136). In some examples, the glass core 132 includes at least one of: aluminosilicate, borosilicate, alumino-borosilicate, silica, and/or fused silica. In some examples, the glass core 132 includes one or more additives including: aluminum oxide (Al₂O₃), boron trioxide (B₂O₃), magnesia oxide (MgO), calcium oxide (CaO), stoichiometric silicon oxide (SrO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the glass core 132 includes silicon and oxygen. In some examples, the glass core 132 includes silicon, oxygen and/or one or more of aluminum, boron, magnesium, calcium, barium, tin, sodium, potassium, strontium, phosphorus, zirconium, lithium, titanium, and/or zinc. In some examples, the glass core 132 includes at least 23 percent silicon by weight and at least 26 percent oxygen by weight. In some examples, the glass core is a layer of glass including silicon, oxygen and aluminum. In some examples, the glass core 132 includes at least 23 percent silicon by weight, at least 26 percent oxygen by weight, and at least 5 percent aluminum by weight.

In some examples, the glass core 132 is an amorphous solid glass layer. In some examples, the glass core 132 is a layer of glass that does not include an organic adhesive or an organic material. In some examples, the glass core 132 is a solid layer of glass having a rectangular shape in plan view. In some examples, the glass core 132, as a glass substrate, includes at least one glass layer and does not include epoxy and does not include glass fibers (e.g., does not include an epoxy-based prepreg layer with glass cloth). In some examples, the core 132 corresponds to a single piece of glass that extends the full height/thickness of the core. In other examples, the glass core 132 can be silicon, a dielectric material and/or any other material(s).

In some examples, the glass core 132 has a rectangular shape that is substantially coextensive, in plan view, with the layers above and/or below the core. In some examples, the glass core 132 has a thickness in a range of about 50 micrometers (μm) to about 1.4 millimeters (mm). In some examples, the glass core 132 can be a multi-layer glass substrate (e.g., a coreless substrate), where a glass layer has a thickness in a range of about 25 μm to about 50 μm. In some examples, the glass core 132 can have dimensions of about 10 mm on a side to about 250 mm on a side (e.g., 10 mm by 10 mm to 250 mm by 250 mm). In some examples, the glass core 132 corresponds to a rectangular prism volume with sections (e.g., vias) removed and filled with other materials (e.g., metal). Among other things, glass cores are advantageous over epoxy-based cores because glass is stiffer and, therefore, provides for greater mechanical support or strength for the package substrate. Thus, the glass core 132 is an example means for strengthening the package substrate.

The first and second build-up regions 134, 136 are represented in FIG. 1 as masses/blocks with the internal interconnects 126 extending in straight lines through the build-up regions 134, 136 (and the glass core 132). However, FIG. 1 has been simplified for the sake of clarity and purposes of explanation. In practice, the interconnects are not necessarily straight. More particularly, in some examples, the build-up regions 134, 136 are defined by alternating layers of dielectric material and layers of conductive material (e.g., a metal such as copper). The conductive (metal) layers serve as the basis for the internal interconnects 126 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers. Further, the electrical routing or traces on either side of the glass core 132 may be electrically coupled by through-glass vias (TGVs) (e.g., copper plated vias) extending through the glass core 132.

Using glass as a starting core material (e.g., the glass core 132 of FIG. 1) has a mechanical benefit (e.g., reduced warpage, smaller thickness variation), an electrical benefit, and a design flexibility benefit (e.g., tighter through hole pitch, finer core routing) over using traditional organic core materials (e.g., epoxy-based prepreg). For example, the glass core 132 can support multi-chip packaging (e.g., embedded multi die interconnect bridge (EMIB), 2.5D/3D heterogeneous integration, hyper chip stacking (silicon (Si) interposers), etc.), reduce first level interconnect (FLI) bump pitches (e.g., less than 30 micrometer (μm)), reduce fine line spacing (FLS) (e.g., 2/2 μm), enable higher density interconnects, enable higher input/output (I/O) density patterning, increase form factors, and decrease package thicknesses relative to the traditional organic core materials.

While glass cores provide a number of benefits and advantages, they also present certain challenges. For instance, differences in the coefficients of thermal expansion (CTEs) between copper and glass results in copper expanding and contracting more than the glass. As a result, the copper in a TGV that extends through a glass core (such as the glass core 132) can expand and contract relative to the glass core during thermal cycles (e.g., during a TGV annealing process and/or subsequent fabrication processes) thereby inducing stress in the glass. Such stress can result in reliability concerns based on a reduction in the strength of the glass core, the formation and/or propagation of cracks in the glass core, and/or other breaks or failures of the glass core. Efforts to mitigate these concerns include the deposition of a thin film liner between the glass core and the copper of a TGV to serve as a buffer that absorbs at least some of the stress induced by the expansion and contraction of the copper relative to the glass. However, many known liners are difficult to apply to the glass and often require expensive equipment for the coating process. Further, many known liners use materials that often crack and/or fail during certain types of plating processes to add copper into TGVs. Further still, many known liners are limited to specific circumstances of particular substrate designs and become less effective for different designs (based on different structures and/or different materials involved).

Examples disclosed herein involve thin film liners made of porous materials that can be applied using easier and less expensive processes than known techniques. Furthermore, in some examples, the porosity of the thin film material can be modulated and reformulated to adapt to different use cases associated with different materials and/or different structures. Furthermore, the example porous thin film materials disclosed herein and the associated methods of application are compatible with any type of TGV plating process.

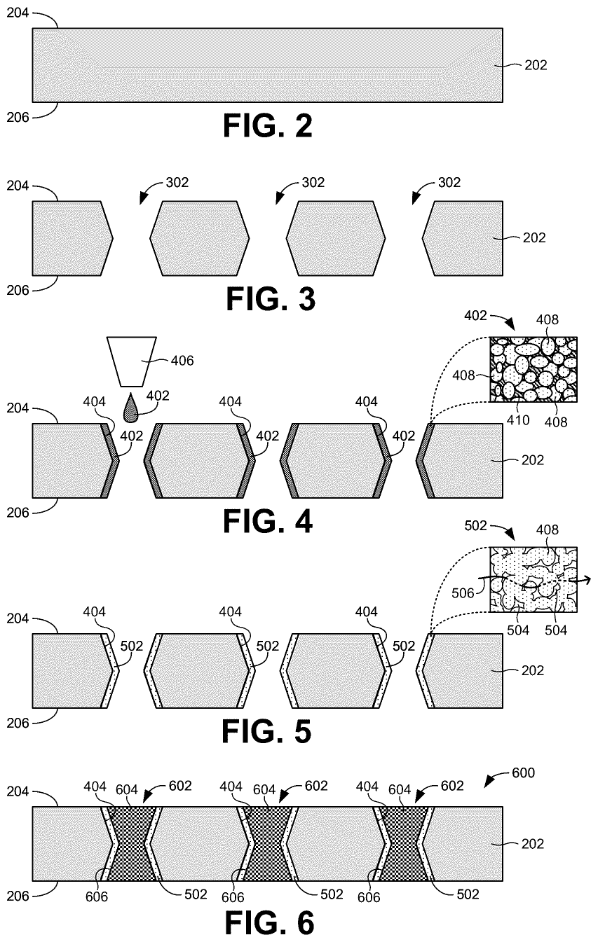

FIGS. 2-6 illustrate various stages in an example fabrication process of an example glass core 600 (the glass core shown in FIG. 6) that may be used to implement the example glass core 132 of FIG. 1. Thus, the description of the glass core 132 of FIG. 1 provided above applies similarly to the example glass core 600 of FIG. 6. FIG. 2 represents a glass panel 202 corresponding to the initial state of the glass core 600. In some examples, the glass panel 202 is fabricated to a thickness (defined between first and second opposing surfaces 204, 206) corresponding to the final thickness of the glass core 600. However, in some examples, the glass panel 202 is initially slightly larger than the final thickness of the glass core 600 to enable some amount of the glass to be removed during subsequent polishing or planarization processes as discussed further below.

FIG. 3 represents the stage of fabrication following the creating of through-holes 302 (e.g., holes, openings, cavities, etc.) that extend through the glass panel 202. In this example, the through-holes 302 define the location of TGVs 602 to be provided in the glass core 600 as shown in FIG. 6. In some examples, the through-holes 302 are created through a laser induced deep etching (LIDE) process. In this example, the through-holes 302 have a cross-sectional profile generally corresponding to an hourglass shape with the width (e.g., diameter) of the through-holes 302 being narrower near a midpoint of the through-holes 302 between the opposing first and second surfaces 204, 206 of the glass panel 202. In other examples, one or more of the through-holes 302 may have a different cross-sectional shape. For instance, in some examples, one or more of the through-holes 302 may have a generally conical or tapered shape with the width (e.g., diameter) being smallest at one of the two surfaces 204, 206 of the glass panel 202 and the width (e.g., diameter) being largest at the opposite surface 204, 206. In other examples, the width (e.g., diameter) of one or more of the through-holes 302 is approximately consistent along a full length of the through-holes 302 between the opposing surfaces 204, 206 of the glass panel 202.

FIG. 4 represents a stage of fabrication that involves the application of a thin film of a material mixture 402 along sidewalls 404 (e.g., inner surfaces, walls, etc.) of the through-holes 302. As represented in the illustrated example of FIG. 4, the material mixture 402 is applied as a liquid or paste from a dispenser 406 (e.g., an inkjet printer). In some examples, the material mixture 402 has a relatively low viscosity so that it easily flows down through the through-holes 302 to coat and/or line the sidewalls 404. As represented by the inset image in FIG. 4, the material mixture 402 includes a structural material 408 and a carrier agent 410. In the illustrated example, the structural material 408 serves as the basis for a final stress absorbing liner 502 (e.g., porous liner, porous material, porous structure, etc.) as shown and described further below in connection with FIG. 5. The carrier agent 410 is employed temporarily to facilitate the application of the structural material but is removed during subsequent processing.

In some examples, as represented in the inset image of FIG. 4, the structural material 408 is a particulate and/or powder (e.g., micro powder and/or nano powder) suspended in the carrier agent 410 that functions as a binder. Additionally or alternatively, in some examples, the structural material 408 is dissolved in the carrier agent 410 that functions as a solvent. In some examples, the structural material 408 can be any suitable type of material including a polymer, a metal, or a ceramic with particles of any suitable size to achieve any suitable mechanical and/or chemical properties for the stress absorbing liner 502. In some examples, the structural material 408 is selected to be compatible with subsequent metallization (e.g., copper plating) processes. In some examples, the structural material 408 is a composite or mixture of multiple different materials. In some examples, the carrier agent 410 is any suitable material capable of suspending the structural material 408 therein (if acting as a binder) or dissolving the structural material 408 (if acting as a solvent) and that is capable of being applied through the dispenser 406 and coated on the sidewalls 404 of the through-holes 302. In some examples, different carrier agents 410 can be used and/or different amounts (relative to the amount of the structural material 408 in the mixture) to modulate the viscosity of the material mixture 402 dispensed onto the glass core for enhanced control of the coating process.

FIG. 5 represents a stage of fabrication following the subsequent processing or treatment of the material mixture 402 applied along the sidewalls 404 of the through-holes 302 as discussed in connection with FIG. 4. More particularly, in this example, the subsequent processing includes a sintering process to bond the structural material 408 powder together. As shown in the inset image in FIG. 5, the distinct particulates of powder are represented as being bonded together into a solid mass corresponding to the stress absorbing liner 502. Further, as shown in FIG. 5, the sintering process results in a porous structure including voids 504 (e.g., pores, gaps, empty spaces, etc.) within the stress absorbing liner 502 that are present due to the removal of the carrier agent 410 during the sintering process. The presence of the voids 504 resulting from the sintering process is why the stress absorbing liner 502 is referred to hereafter as a porous material. The porous material 502 can be fabricated to have any suitable porosity (e.g., at least 5%, at least 10%, at least 15%, at least 25%, at least 50%, at least 75%, as high as 90%, etc.). In some examples, the porosity is dependent on the material composition of the structural material 408 (e.g., the size and/or material(s) of the particulates in the powder) and on the parameters of the sintering process (e.g., temperature and duration of the process).

In some examples, the voids 504 between different portions of the bonded structural material 408 are interconnected (e.g., in communication) to define an open channel 506 (e.g., an open fluid path, a fluid channel, etc.) that extends through a thickness of the porous material 502. That is, in some examples, the porous material 502 has an open-form matrix (e.g., an open-cell porous structure). Notably, the open channel 506 may not be straight but tortuous as represented by the arrow representing the channel 506 in FIG. 5. In some examples, some or all of the voids 504 may be discrete and isolated from one another (e.g., a closed-cell porous structure).

As discussed above, in some examples, the structural material 408 is a polymer (e.g., a polymer solution) dissolved within a solvent (e.g., the carrier agent 410). In some such examples, the subsequent processing of the material mixture 402 results in a cross-linked polymer matrix to produce the final porous material 502 represented in FIG. 5. In some such examples, the subsequent process is based on non-solvent induced phase separation. That is, in some examples, after the material mixture 402 is applied to the glass panel 202, a non-solvent (e.g., water) is sprayed or otherwise dispensed onto the structural material 408. In some examples, the glass panel 202 is dipped into a bath of the non-solvent. The non-solvent causes the material mixture 402 (that includes the polymer-based structural material 408 contained (e.g., dissolved) within the carrier agent 410) to separate into a polymer-rich phase and a polymer-poor phase. The polymer-rich phase defines the structural matrix of the final porous material 502 that is dried, cured, and/or set by the application of heat (e.g., in an oven) which results in the removal of the polymer-poor phase (including the non-solvent) to define the voids 504 within the porous material 502.

As with the powder-based approach discussed above, this non-solvent induced phase separation approach can be implemented with any suitable polymers to achieve any suitable mechanical and/or chemical properties as well as any suitable porosity and/or pore size for the porous material 502. Further, similar to what is discussed above, the nature of the non-solvent induced phase separation process results in an open-cell porous structure with continuous fluid channel(s) (e.g., the open channel 506) extending through the porous material 502.

In some examples, the material mixture 402 dispensed within the through-holes 302 (as represented in FIG. 4) may at least partially accumulate and/or spread on the first (e.g., upper) surface 204 of the glass panel 202. Further, in some examples, the material mixture 402 may attach to the second (e.g., lower) surface 206. As a result, in some examples, the final porous material 502 can at least partially cover the first and/or second surfaces 204, 206 of the glass panel 202. In some such examples, these excess portions of the porous material 502 are removed by a polishing and/or grinding process (e.g., a chemical mechanical planarization (CMP) process).

FIG. 6 represents a stage of fabrication following a metallization process during which a conductive material 604 (e.g., metal, such as copper) is deposited (e.g., plated) to fill the through-holes 302. The through-holes 302 filled with the conductive material 604 define the complete structure of the TGVs 602 and the complete fabrication of the example glass core 600. As discussed above, there is a relatively significant mismatch in CTE between the conductive material 604 and the glass panel 202. However, in this example, the voids 504 within the porous material 502 enable the porous material 502 to deform to thereby absorb stress and/or strain from expansion and/or contraction of the conductive material 604 relative to the glass panel 202 during the TGV annealing process and/or other thermal cycles. In some examples, the amount and/or size of the voids 504 (e.g., the porosity of the porous material) can affect the tolerance to stress and/or strain the porous material 502 is able to absorb. Accordingly, as discussed above, the porosity of the material can be modulated or tuned differently in different applications and/or use cases.

In the illustrated example of FIG. 6, the porous material 502 positioned between the inner sidewalls 404 of the through-holes 302 and outer sidewalls 606 of the conductive material 604 is shown to be substantially consistent along the full length of the TGVs 602. However, in some examples, the thickness of the porous material 502 can have different thicknesses at different heights or depths along the length of the TGVs 602. Variability in thickness of the porous material 502 along the length of the TGVs 602 can arise from the way in which the porous material 502 is initially applied to the sidewalls 404 (as the dispensed material mixture 402 shown in FIG. 4). Specifically, the lining or coating of the sidewalls 404 of the through-holes 302 by the thin film of material mixture 402 is achieved, at least in part, based on gravity and is affected by the viscosity of the material mixture 402. As such, the material mixture 402 may accumulate more at some depths than others resulting in differences in thickness in the final porous material 502. In some examples, the thickness of the porous material 502 is less than 10 micrometers and, in some examples, considerably less (e.g., 5 micrometers or less, 1 micrometer or less, 500 nanometers or less, 250 nanometers or less, 100 nanometers or less).

Significantly, the highest amounts of stress induced by the CTE mismatch between the conductive material 604 and the glass panel 202 typically occur at the ends of the TGVs 602 (e.g., adjacent the first and second surfaces 204, 206). Accordingly, in some examples, the dispensing of the material mixture 402 is controlled to achieve a suitable thickness at those regions with less concern for the thickness of the material mixture 402 (and the resulting porous material 502) at other regions (e.g., near a midpoint of the TGVs 602). In some examples, controlling the thickness of the material mixture 402 is achieved by balancing out (e.g., tuning, adjusting, optimizing, etc.) the material properties (e.g., viscosity, surface tension, etc.) with the process parameters (e.g., jetting rate, vacuum pulling from the backside, temperature, etc.).

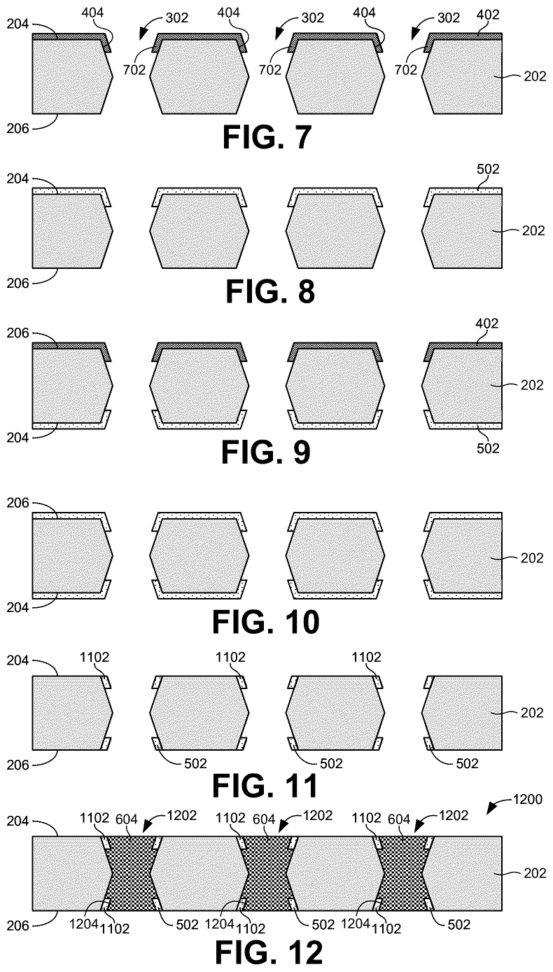

FIGS. 7-12 illustrate various stages in another example fabrication process of another example glass core 1200 (the glass core shown in FIG. 12) that may be used to implement the example glass core 132 of FIG. 1. Thus, the description of the glass core 132 of FIG. 1 provided above applies similarly to the example glass core 1200 of FIG. 12. The process to fabricate the example glass core 1200 shown in FIG. 12 begins with the same process detailed above in connection with FIGS. 2 and 3. That is, the stage of fabrication represented in FIG. 7 assumes that the glass panel 202 has been provided and that the through-holes 302 have been added. FIG. 7 represents the stage of fabrication following the subsequent application of the material mixture 402 (including the structural material 408 and the carrier agent 410 as described above) across the first surface 204 of the glass panel 202. That is, rather than dispensing the material mixture 402 at localized spots corresponding with the locations of the through-holes 302 (as shown in FIG. 4), in the example of FIG. 7, the material mixture 402 is dispensed across the entire upward facing surface (e.g., the first surface 204) of the glass panel 202. In some examples, the material mixture 402 is applied through a spin coating process. In other examples, the material mixture 402 is applied through a slit coating process. Due to the presence of the through-holes 302, portions 702 of the material will flow into the through-holes 302 to line or coat an upper end of the sidewalls 404 of the through-holes 302. However, in some examples, unlike what is shown in FIG. 4, the portions 702 extend less than the full length of the through-holes 302. In some examples, the portions 702 extend a relatively small distance (e.g., depth) into the through-holes 302 (e.g., 20 micrometers or less, 15 micrometers or less, 10 micrometers or less, 5 micrometers or less, 1 micrometer or less, etc.) compared to the full length of the through-holes 302 corresponding to the thickness of the glass panel 202, which can be at least 600 micrometers thick.

FIG. 8 represents a stage of fabrication following subsequent processing or treatment of the material mixture 402 to produce the porous material 502. In some examples, this subsequent processing can follow any of the processes detailed above in connection with FIG. 5 (e.g., a sintering process, a non-solvent induced phase separation process, etc.).

FIG. 9 represents a stage of fabrication following the flipping of the glass panel 202 so that the second surface 206 faces upwards followed by the dispensing of another layer of the material mixture 402 across the second surface 206. FIG. 10 represents a stage of fabrication following the subsequent processing and/or treatment of the second layer of material mixture 402 to produce a second layer of the porous material 502 on the second surface 206. In other words, the processes implemented on a first side of the glass panel 202 (e.g., on the first surface 204) detailed in FIGS. 7 and 8 are repeated on the opposite side (e.g., on the second surface 206) as represented in FIGS. 9 and 10.

FIG. 11 represents a stage of fabrication following a polishing or grinding process (e.g., a CMP process) to remove the porous material 502 from the first and second surfaces 204, 206 of the glass panel 202. Thus, as shown in FIG. 11, what remains are relatively small segments 1102 of the porous material 502 along discrete portions the sidewalls 404 of the through-holes 302 at each end of the through-holes 302. In this example, the discrete portions of the sidewalls 404 are separated by another portion of the sidewall 404 that is not covered or coated by the porous material 502.

FIG. 12 represents a stage of fabrication following a metallization process (similar to what is described above in connection with FIG. 6) during which the conductive material 604 is deposited (e.g., plated) to fill the through-holes 302. The through-holes 302 filled with the conductive material 604 define the complete structure of the TGVs 1202 and the complete fabrication of the example glass core 1200. In this example, the segments 1102 of the porous material 502 circumferentially surround the opposing ends of the outer sidewall 1204 of the conductive material 604. However, the porous material 502 is spaced apart from a central segment of the TGVs 1202. As discussed above, the highest stress concentrations due to the CTE mismatch between the conductive material 604 and the glass panel 202 occur at the ends of the TGVs 1202. Thus, the absence of the porous material 502 near the central segment of the TGV 1202 does not pose a serious concern affecting the reliability and structural integrity of the glass core 1200.

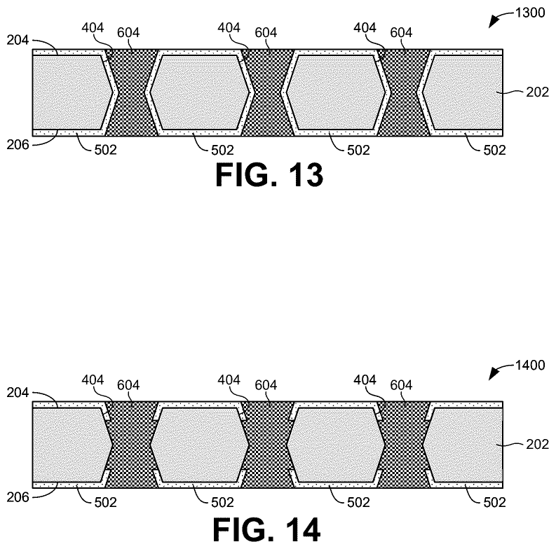

FIG. 13 illustrates another example glass core 1300 that may be used to implement the example glass core 132 of FIG. 1. Thus, the description of the glass core 132 of FIG. 1 provided above applies similarly to the example glass core 1300 of FIG. 13. The example glass core 1300 of FIG. 13 is substantially the same as the glass core 600 of FIG. 6 and can be fabricated in substantially the same way. However, unlike what was described in connection with FIGS. 2-6, in the example of FIG. 13, the material mixture 402 is not merely applied locally within the through-holes 302. Instead, in this example, the material mixture 402 is applied across the entire outer surface of the glass panel 202. As such, the resulting porous material 502 extends along the first and second surfaces 204, 206 of the glass panel 202 as well as along the sidewalls 404 of the through-holes 302. Further, unlike what was described above in connection with FIGS. 2-6, in the example of FIG. 13, the porous material 502 is not polished or ground away but is retained on the glass panel 202 as shown. In this way, the porous material 502 can serve as a buffer layer between the glass panel 202 and materials added onto the glass panel 202 (e.g., associated with the build-up regions 134, 136 of FIG. 1).

FIG. 14 illustrates another example glass core 1400 that may be used to implement the example glass core 132 of FIG. 1. Thus, the description of the glass core 132 of FIG. 1 provided above applies similarly to the example glass core 1400 of FIG. 14. The example glass core 1400 of FIG. 14 is substantially the same as the glass core 1200 of FIG. 12 and can be fabricated in substantially the same way. However, in the example of FIG. 14, rather than removing the porous material 502 from the first and second surfaces 204, 206 of the glass panel 202 (as described in connection with FIGS. 11 and 12), the porous material 502 is retained on the glass panel 202 as shown. In this way, the porous material 502 can serve as a buffer layer between the glass panel 202 and materials added onto the glass panel 202 (e.g., associated with the build-up regions 134, 136 of FIG. 1).

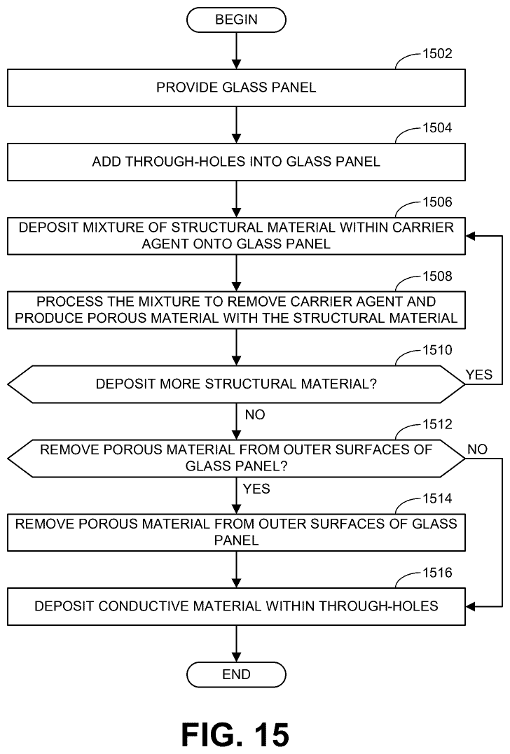

FIG. 15 is a flowchart representative of an example method of manufacturing any one of the example glass cores 600, 1200, 1300, 1400 of FIGS. 6 and/or 12-14 that may be implemented in the example IC package 100 of FIG. 1. In some examples, some or all of the operations outlined in the example method of FIG. 15 are performed automatically by fabrication equipment that is programmed to perform the operations. Although the example method of manufacture is described with reference to the flowchart illustrated in FIG. 15, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example process begins at block 1502 by providing a glass panel (such as the glass panel 202 shown in FIG. 2). At block 1504, the example process involves adding through-holes (such as the through-holes 302 shown in FIG. 3) into the glass panel 202. At block 1506, the example process involves depositing a mixture of a structural material within a carrier agent (such as the material mixture 402 including the structural material 408 within the carrier agent 410 as shown in FIGS. 4, 7, and 9). In some examples, the mixture 402 is dispensed at localized spots associated with the through-holes 302 so that the mixture will coat or line the sidewalls 404 of the through-holes 302 (as represented in FIG. 4). Additionally or alternatively, in some examples, the mixture 402 is dispensed across an entire outer surface of the glass panel 202 (e.g., via spin coating, slit coating, etc.) and the mixture 402 then flows at least partially into the through-holes 302 (as represented in FIG. 7).

At block 1508, the example process involves processing the mixture 402 to remove the carrier agent 410 and produce a porous material (e.g., the porous material 502 shown in FIGS. 5, 8, and 10) with the structural material 408. In some examples, this is achieved through a sintering process. Additionally or alternatively, in some examples, this is achieved through a non-solvent induced phase separation process.

At block 1510, the example process involves determining whether to deposit more of the mixture 402. For instance, in the example described above in connection with FIGS. 7-12, a first layer of the mixture 402 was added to a first side of the glass panel 202 and subsequently processed before the process is repeated on the second side of the glass panel 202. If more of the mixture 402 is to be deposited, the process returns to block 1506. Otherwise, the process advances to block 1512.

At block 1512, the example process involves determining whether to remove the porous material 502 from the outer surfaces (e.g., the first and second surfaces 204, 206) of the glass panel 202. If so (e.g., to fabricate the example glass cores 600, 1200 of FIGS. 6 and/or 12), the process advances to block 1514 where the porous material 502 is removed from the outer surfaces 204, 206 of the glass panel 202. Thereafter, the process advances to block 1516. Returning to block 1512, if the porous material 502 is not to be removed (e.g., to fabricate the example glass cores 1300, 1400 of FIGS. 13 and/or 14), the process advances directly to block 1516.

At block 1516, the example process involves depositing (e.g., plating) a conductive material (e.g., the conductive material 604 shown in FIGS. 6, 12, 13, and 14). within the through-holes 302. Thereafter, the example process of FIG. 15 ends.

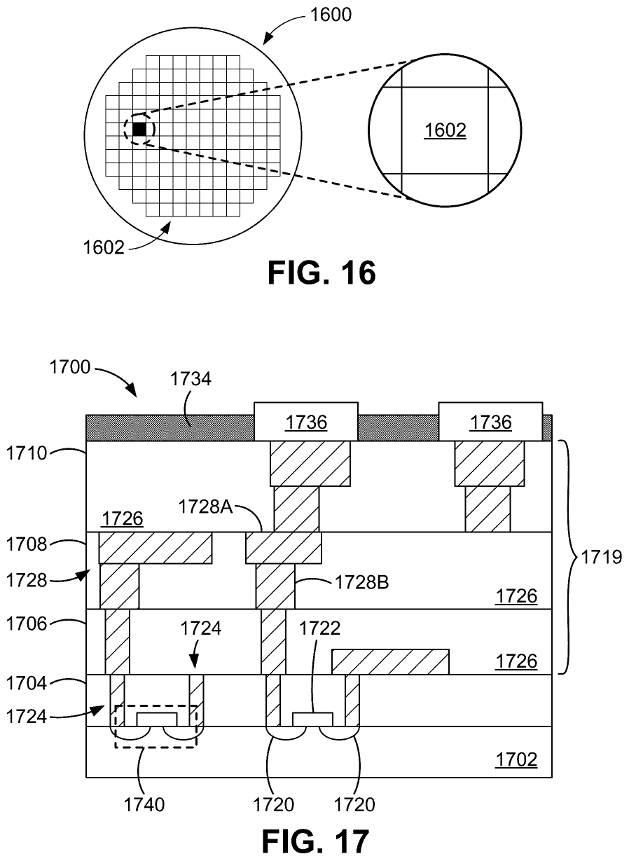

The example IC package 100 including any one of the example glass cores 600, 1200, 1300, 1400 of FIGS. 6 and 12-14 disclosed herein may be included in any suitable electronic component. FIGS. 16-19 illustrate various examples of apparatus that may include or be included in the IC package 100 disclosed herein.

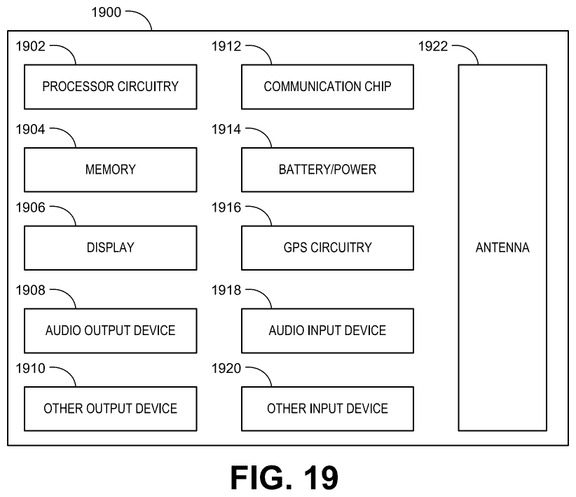

FIG. 16 is a top view of a wafer 1600 and dies 1602 that may be included in the IC package 100 of FIG. 1 (e.g., as any suitable ones of the dies 108, 110). The wafer 1600 includes semiconductor material and one or more dies 1602 having circuitry. Each of the dies 1602 may be a repeating unit of a semiconductor product. After the fabrication of the semiconductor product is complete, the wafer 1600 may undergo a singulation process in which the dies 1602 are separated from one another to provide discrete “chips.” The die 1602 includes one or more transistors (e.g., some of the transistors 1740 of FIG. 17, discussed below), supporting circuitry to route electrical signals to the transistors, passive components (e.g., traces, resistors, capacitors, inductors, and/or other circuitry), and/or any other components. In some examples, the die 1602 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1602. For example, a memory array of multiple memory circuits may be formed on a same die 1602 as programmable circuitry (e.g., the processor circuitry 1902 of FIG. 19) and/or other logic circuitry. Such memory may store information for use by the programmable circuitry. The example IC package 100 disclosed herein may be manufactured using a die-to-wafer assembly technique in which some dies are attached to a wafer 1600 that includes others of the dies, and the wafer 1600 is subsequently singulated.

FIG. 17 is a cross-sectional side view of an IC device 1700 that may be included in the example IC package 100 (e.g., in any one of the dies 108, 110). One or more of the IC devices 1700 may be included in one or more dies 1602 (FIG. 16). The IC device 1700 may be formed on a die substrate 1702 (e.g., the wafer 1600 of FIG. 16) and may be included in a die (e.g., the die 1602 of FIG. 16). The die substrate 1702 may be a semiconductor substrate including semiconductor materials including, for example, n-type or p-type materials systems (or a combination of both). The die substrate 1702 may include, for example, a crystalline substrate formed using a bulk silicon or a silicon-on-insulator (SOI) substructure. In some examples, the die substrate 1702 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1702. Although a few examples of materials from which the die substrate 1702 may be formed are described here, any material that may serve as a foundation for an IC device 1700 may be used. The die substrate 1702 may be part of a singulated die (e.g., the dies 1602 of FIG. 16) or a wafer (e.g., the wafer 1600 of FIG. 16).

The IC device 1700 may include one or more device layers 1704 disposed on and/or above the die substrate 1702. The device layer 1704 may include features of one or more transistors 1740 (e.g., metal oxide semiconductor field-effect transistors (MOSFETs)) formed on the die substrate 1702. The device layer 1704 may include, for example, one or more source and/or drain (S/D) regions 1720, a gate 1722 to control current flow between the S/D regions 1720, and one or more S/D contacts 1724 to route electrical signals to/from the S/D regions 1720. The transistors 1740 may include additional features not depicted for the sake of clarity, such as device isolation regions, gate contacts, and the like. The transistors 1740 are not limited to the type and configuration depicted in FIG. 17 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1740 may include a gate 1722 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1740 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1740 along the source-channel-drain direction, the gate electrode may include a U-shaped structure that includes a bottom portion substantially parallel to the surface of the die substrate 1702 and two sidewall portions that are substantially perpendicular to the top surface of the die substrate 1702. In other examples, at least one of the metal layers that form the gate electrode may be a planar layer that is substantially parallel to the top surface of the die substrate 1702 and does not include sidewall portions substantially perpendicular to the top surface of the die substrate 1702. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1720 may be formed within the die substrate 1702 adjacent to the gate 1722 of corresponding transistor(s) 1740. The S/D regions 1720 may be formed using an implantation/diffusion process or an etching/deposition process, for example. In the former process, dopants such as boron, aluminum, antimony, phosphorous, or arsenic may be ion-implanted into the die substrate 1702 to form the S/D regions 1720. An annealing process that activates the dopants and causes them to diffuse farther into the die substrate 1702 may follow the ion-implantation process. In the latter process, the die substrate 1702 may first be etched to form recesses at the locations of the S/D regions 1720. An epitaxial deposition process may then be carried out to fill the recesses with material that is used to fabricate the S/D regions 1720. In some implementations, the S/D regions 1720 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1720 may be formed using one or more alternate semiconductor materials such as germanium or a group III-V material or alloy. In further examples, one or more layers of metal and/or metal alloys may be used to form the S/D regions 1720.

Electrical signals, such as power and/or input/output (I/O) signals, may be routed to and/or from the devices (e.g., transistors 1740) of the device layer 1704 through one or more interconnect layers disposed on the device layer 1704 (illustrated in FIG. 17 as interconnect layers 1706-2010). For example, electrically conductive features of the device layer 1704 (e.g., the gate 1722 and the S/D contacts 1724) may be electrically coupled with the interconnect structures 1728 of the interconnect layers 1706-2010. The one or more interconnect layers 1706-2010 may form a metallization stack (also referred to as an “ILD stack”) 1719 of the IC device 1700.

The interconnect structures 1728 may be arranged within the interconnect layers 1706-2010 to route electrical signals according to a wide variety of designs (in particular, the arrangement is not limited to the particular configuration of interconnect structures 1728 depicted in FIG. 17). Although a particular number of interconnect layers 1706-2010 is depicted in FIG. 17, examples of the present disclosure include IC devices having more or fewer interconnect layers than depicted.

In some examples, the interconnect structures 1728 may include lines 1728a and/or vias 1728b filled with an electrically conductive material such as a metal. The lines 1728a may be arranged to route electrical signals in a direction of a plane that is substantially parallel with a surface of the die substrate 1702 upon which the device layer 1704 is formed. For example, the lines 1728a may route electrical signals in a direction in and/or out of the page from the perspective of FIG. 17. The vias 1728b may be arranged to route electrical signals in a direction of a plane that is substantially perpendicular to the surface of the die substrate 1702 upon which the device layer 1704 is formed. In some examples, the vias 1728b may electrically couple lines 1728a of different interconnect layers 1706-2010 together.

The interconnect layers 1706-2010 may include a dielectric material 1726 disposed between the interconnect structures 1728, as shown in FIG. 17. In some examples, the dielectric material 1726 disposed between the interconnect structures 1728 in different ones of the interconnect layers 1706-2010 may have different compositions; in other examples, the composition of the dielectric material 1726 between different interconnect layers 1706-2010 may be the same.

A first interconnect layer 1706 (referred to as Metal 1 or “M1”) may be formed directly on the device layer 1704. In some examples, the first interconnect layer 1706 may include lines 1728a and/or vias 1728b, as shown. The lines 1728a of the first interconnect layer 1706 may be coupled with contacts (e.g., the S/D contacts 1724) of the device layer 1704.

A second interconnect layer 1708 (referred to as Metal 2 or “M2”) may be formed directly on the first interconnect layer 1706. In some examples, the second interconnect layer 1708 may include vias 1728b to couple the lines 1728a of the second interconnect layer 1708 with the lines 1728a of the first interconnect layer 1706. Although the lines 1728a and the vias 1728b are structurally delineated with a line within each interconnect layer (e.g., within the second interconnect layer 1708) for the sake of clarity, the lines 1728a and the vias 1728b may be structurally and/or materially contiguous (e.g., simultaneously filled during a dual-damascene process) in some examples.

A third interconnect layer 1710 (referred to as Metal 3 or “M3”) (and additional interconnect layers, as desired) may be formed in succession on the second interconnect layer 1708 according to similar techniques and/or configurations described in connection with the second interconnect layer 1708 or the first interconnect layer 1706. In some examples, the interconnect layers that are “higher up” in the metallization stack 1719 in the IC device 1700 (i.e., further away from the device layer 1704) may be thicker.

The IC device 1700 may include a solder resist material 1734 (e.g., polyimide or similar material) and one or more conductive contacts 1736 formed on the interconnect layers 1706-2010. In FIG. 17, the conductive contacts 1736 are illustrated as taking the form of bond pads. The conductive contacts 1736 may be electrically coupled with the interconnect structures 1728 and configured to route the electrical signals of the transistor(s) 1740 to other external devices. For example, solder bonds may be formed on the one or more conductive contacts 1736 to mechanically and/or electrically couple a chip including the IC device 1700 with another component (e.g., a circuit board). The IC device 1700 may include additional or alternate structures to route the electrical signals from the interconnect layers 1706-2010; for example, the conductive contacts 1736 may include other analogous features (e.g., posts) that route the electrical signals to external components.

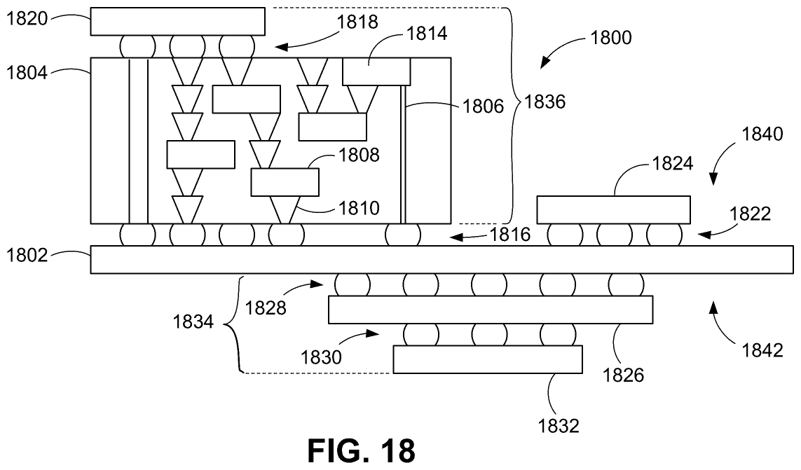

FIG. 18 is a cross-sectional side view of an IC device assembly 1800 that may include the IC package 100 disclosed herein. In some examples, the IC device assembly corresponds to the IC package 100. The IC device assembly 1800 includes a number of components disposed on a circuit board 1802 (which may be, for example, a motherboard). The IC device assembly 1800 includes components disposed on a first face 1840 of the circuit board 1802 and an opposing second face 1842 of the circuit board 1802; generally, components may be disposed on one or both faces 1840 and 1842. Any of the IC packages discussed below with reference to the IC device assembly 1800 may take the form of the example IC package 100 of FIG. 1.

In some examples, the circuit board 1802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1802. In other examples, the circuit board 1802 may be a non-PCB substrate.

The IC device assembly 1800 illustrated in FIG. 18 includes a package-on-interposer structure 1836 coupled to the first face 1840 of the circuit board 1802 by coupling components 1816. The coupling components 1816 may electrically and mechanically couple the package-on-interposer structure 1836 to the circuit board 1802, and may include solder balls (as shown in FIG. 18), male and female portions of a socket, an adhesive, an underfill material, and/or any other suitable electrical and/or mechanical coupling structure.

The package-on-interposer structure 1836 may include an IC package 1820 coupled to an interposer 1804 by coupling components 1818. The coupling components 1818 may take any suitable form for the application, such as the forms discussed above with reference to the coupling components 1816. Although a single IC package 1820 is shown in FIG. 18, multiple IC packages may be coupled to the interposer 1804; indeed, additional interposers may be coupled to the interposer 1804. The interposer 1804 may provide an intervening substrate used to bridge the circuit board 1802 and the IC package 1820. The IC package 1820 may be or include, for example, a die (the die 1602 of FIG. 16), an IC device (e.g., the IC device 1700 of FIG. 17), or any other suitable component. Generally, the interposer 1804 may spread a connection to a wider pitch or reroute a connection to a different connection. For example, the interposer 1804 may couple the IC package 1820 (e.g., a die) to a set of BGA conductive contacts of the coupling components 1816 for coupling to the circuit board 1802. In the example illustrated in FIG. 18, the IC package 1820 and the circuit board 1802 are attached to opposing sides of the interposer 1804; in other examples, the IC package 1820 and the circuit board 1802 may be attached to a same side of the interposer 1804. In some examples, three or more components may be interconnected by way of the interposer 1804.

In some examples, the interposer 1804 may be formed as a PCB, including multiple metal layers separated from one another by layers of dielectric material and interconnected by electrically conductive vias. In some examples, the interposer 1804 may be formed of an epoxy resin, a fiberglass-reinforced epoxy resin, an epoxy resin with inorganic fillers, a ceramic material, or a polymer material such as polyimide. In some examples, the interposer 1804 may be formed of alternate rigid or flexible materials that may include the same materials described above for use in a semiconductor substrate, such as silicon, germanium, and other group III-V and group IV materials. The interposer 1804 may include metal interconnects 1808 and vias 1810, including but not limited to through-silicon vias (TSVs) 1806. The interposer 1804 may further include embedded devices 1814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1804. The package-on-interposer structure 1836 may take the form of any of the package-on-interposer structures known in the art.

The IC device assembly 1800 may include an IC package 1824 coupled to the first face 1840 of the circuit board 1802 by coupling components 1822. The coupling components 1822 may take the form of any of the examples discussed above with reference to the coupling components 1816, and the IC package 1824 may take the form of any of the examples discussed above with reference to the IC package 1820.

The IC device assembly 1800 illustrated in FIG. 18 includes a package-on-package structure 1834 coupled to the second face 1842 of the circuit board 1802 by coupling components 1828. The package-on-package structure 1834 may include a first IC package 1826 and a second IC package 1832 coupled together by coupling components 1830 such that the first IC package 1826 is disposed between the circuit board 1802 and the second IC package 1832. The coupling components 1828, 1830 may take the form of any of the examples of the coupling components 1816 discussed above, and the IC packages 1826, 1832 may take the form of any of the examples of the IC package 1820 discussed above. The package-on-package structure 1834 may be configured in accordance with any of the package-on-package structures known in the art.

FIG. 19 is a block diagram of an example electrical device 1900 that may include one or more of the example IC package 100. For example, any suitable ones of the components of the electrical device 1900 may include one or more of the device assemblies 1800, IC devices 1700, or dies 1602 disclosed herein, and may be arranged in the example IC package 100. A number of components are illustrated in FIG. 19 as included in the electrical device 1900, but any one or more of these components may be omitted or duplicated, as suitable for the application. In some examples, some or all of the components included in the electrical device 1900 may be attached to one or more motherboards. In some examples, some or all of these components are fabricated onto a single system-on-a-chip (SoC) die.

Additionally, in various examples, the electrical device 1900 may not include one or more of the components illustrated in FIG. 19, but the electrical device 1900 may include interface circuitry for coupling to the one or more components. For example, the electrical device 1900 may not include a display 1906, but may include display interface circuitry (e.g., a connector and driver circuitry) to which a display 1906 may be coupled. In another set of examples, the electrical device 1900 may not include an audio input device 1918 (e.g., microphone) or an audio output device 1908 (e.g., a speaker, a headset, earbuds, etc.), but may include audio input or output device interface circuitry (e.g., connectors and supporting circuitry) to which an audio input device 1918 or audio output device 1908 may be coupled.

The electrical device 1900 may include programmable circuitry 1902 (e.g., one or more processing devices). The programmable circuitry 1902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1900 may include a memory 1904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1904 may include memory that shares a die with the programmable circuitry 1902. This memory may be used as cache memory and may include embedded dynamic random access memory (eDRAM) or spin transfer torque magnetic random access memory (STT-MRAM).

In some examples, the electrical device 1900 may include a communication chip 1912 (e.g., one or more communication chips). For example, the communication chip 1912 may be configured for managing wireless communications for the transfer of data to and from the electrical device 1900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1912 may operate in accordance with other wireless protocols in other examples. The electrical device 1900 may include an antenna 1922 to facilitate wireless communications and/or to receive other wireless communications (such as AM or FM radio transmissions).

In some examples, the communication chip 1912 may manage wired communications, such as electrical, optical, or any other suitable communication protocols (e.g., the Ethernet). As noted above, the communication chip 1912 may include multiple communication chips. For instance, a first communication chip 1912 may be dedicated to shorter-range wireless communications such as Wi-Fi or Bluetooth, and a second communication chip 1912 may be dedicated to longer-range wireless communications such as global positioning system (GPS), EDGE, GPRS, CDMA, WiMAX, LTE, EV-DO, or others. In some examples, a first communication chip 1912 may be dedicated to wireless communications, and a second communication chip 1912 may be dedicated to wired communications.

The electrical device 1900 may include battery/power circuitry 1914. The battery/power circuitry 1914 may include one or more energy storage devices (e.g., batteries or capacitors) and/or circuitry for coupling components of the electrical device 1900 to an energy source separate from the electrical device 1900 (e.g., AC line power).

The electrical device 1900 may include a display 1906 (or corresponding interface circuitry, as discussed above). The display 1906 may include any visual indicators, such as a heads-up display, a computer monitor, a projector, a touchscreen display, a liquid crystal display (LCD), a light-emitting diode display, or a flat panel display.

The electrical device 1900 may include an audio output device 1908 (or corresponding interface circuitry, as discussed above). The audio output device 1908 may include any device that generates an audible indicator, such as speakers, headsets, or earbuds.

The electrical device 1900 may include an audio input device 1918 (or corresponding interface circuitry, as discussed above). The audio input device 1918 may include any device that generates a signal representative of a sound, such as microphones, microphone arrays, or digital instruments (e.g., instruments having a musical instrument digital interface (MIDI) output).

The electrical device 1900 may include GPS circuitry 1916. The GPS circuitry 1916 may be in communication with a satellite-based system and may receive a location of the electrical device 1900, as known in the art.

The electrical device 1900 may include any other output device 1910 (or corresponding interface circuitry, as discussed above). Examples of the other output device 1910 may include an audio codec, a video codec, a printer, a wired or wireless transmitter for providing information to other devices, or an additional storage device.

The electrical device 1900 may include any other input device 1920 (or corresponding interface circuitry, as discussed above). Examples of the other input device 1920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1900 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that include a porous material as a thin film liner between the conductive material of TGVs in a glass core and the surrounding sidewalls of the through-hole within which the conductive material is disposed. The porous nature of the material allows for deformation to absorb stress and/or strain that can arise, for example, from a CTE mismatch between the conductive material and the surrounding glass.

Further examples and combinations thereof include the following:

Example 1 includes an apparatus comprising a glass layer having a through-hole, a conductive material within the through-hole, and a porous material between at least a portion of the conductive material and at least a portion of a sidewall of the through-hole.

Example 2 includes the apparatus of example 1, wherein the at least the portion of the sidewall includes a first portion adjacent a first end of the through-hole, and the porous material is between the conductive material and at least a second portion of the sidewall adjacent a second end of the through-hole, at least a third portion of the sidewall between the at least the first portion and the at least the second portion, the porous material spaced apart from the at least the third portion.

Example 3 includes the apparatus of example 2, wherein the at least the first portion extends a first length along the through-hole, the at least the second portion extends a second length along the through-hole, and the at least the third portion extends a third length along the through-hole, the third length greater than the first length and greater than the second length.

Example 4 includes the apparatus of example 3, wherein the first and second lengths are less than 20 micrometers.

Example 5 includes the apparatus of any one of examples 1-4, wherein the porous material extends a full length along the sidewall of the through-hole from opposing first and second surfaces of the glass layer.

Example 6 includes the apparatus of example 5, wherein the porous material has a first thickness on the sidewall adjacent the first surface and a second thickness on the sidewall adjacent the second surface, the first thickness different from the second thickness.

Example 7 includes the apparatus of any one of examples 1-6, wherein the porous material is defined by a plurality of pores within a polymer matrix, and adjacent ones of the pores define an open channel through a thickness of the porous material.

Example 8 includes the apparatus of any one of examples 1-7, wherein the glass layer includes a first surface and a second surface opposite the first surface, the through-hole extends between the first and second surfaces, and the porous material extends along at least one of the first surface or the second surface.

Example 9 includes the apparatus of any one of examples 1-8, wherein the glass layer includes a first surface and a second surface opposite the first surface, the through-hole extends between the first and second surfaces, the porous material spaced apart from the first and second surfaces.

Example 10 includes the apparatus of any one of examples 1-9, wherein the porous material includes at least one of a polymer or a ceramic.

Example 11 includes the apparatus of any one of examples 1-10, wherein the porous material includes a metal.

Example 12 includes an apparatus comprising a glass core having a first surface and a second surface opposite the first surface, the glass core including an opening, the opening including a metal extending between the first and second surfaces, and a material coating an inner surface of the opening between the metal and the inner surface, the material including voids, the voids providing a porosity of at least 10%.

Example 13 includes the apparatus of example 12, wherein the material coats less than all of the inner surface of the opening.

Example 14 includes the apparatus of any one of examples 12 or 13, wherein the voids define at least one fluid channel.

Example 15 includes the apparatus of any one of examples 12-14, wherein a thickness of the material differs at different depths within the opening.

Example 16 includes the apparatus of any one of examples 12-15, wherein the material coats the first surface of the glass core.

Example 17 includes an apparatus comprising a semiconductor die, a substrate to support the semiconductor die, the substrate including a glass core, the glass core having a through-glass via (TGV) extending therethrough, the TGV including metal electrically coupled to the semiconductor die, and a porous liner at least partially surrounding an outer sidewall of the metal in the TGV.

Example 18 includes the apparatus of example 17, wherein the porous liner completely surrounds the outer sidewall of the metal along a full length of the TGV.

Example 19 includes the apparatus of any one of examples 17 or 18, wherein the porous liner at least partially surrounds opposing ends of the outer sidewall of the metal and is spaced apart from a central segment of the TGV.

Example 20 includes the apparatus of any one of examples 17-19, wherein the porous liner has a porosity of at least 25%.

Example 21 includes a method comprising providing a through-hole in a glass core, depositing a mixture onto a sidewall of the through-hole, the mixture including a material within a carrier agent, processing the glass core to remove the carrier agent and cause the material to produce a porous structure, and depositing a conductive material within the through-hole, the porous structure between the sidewall of the through-hole and the conductive material.

Example 22 includes the method of example 21, wherein the carrier agent is a liquid solvent and the depositing of the mixture is implemented by at least one of slit coating or spin coating the mixture across a surface of the glass core.

Example 23 includes the method of example 22, wherein the mixture is deposited on a first side of the glass core in a first coating process and a second side of the glass core in a second coating process, a first portion of the mixture to extend partially into the through-hole at a first end adjacent the first side of the glass core during the first coating process, a second portion of the mixture to extend partially into the through-hole at a second end adjacent the second side of the glass core during the second coating process.

Example 24 includes the method of example 23, wherein the second portion of the mixture is to remain spaced apart from the first portion of the mixture.

Example 25 includes the method of any one of examples 22-24, wherein the material is a polymer and the processing of the glass core includes applying a non-solvent liquid to facilitate removal of the carrier agent.

Example 26 includes the method of example 25, wherein the processing of the glass core includes applying heat to remove the non-solvent liquid.

Example 27 includes the method of any one of examples 21-26, wherein the material is at least one of a micro powder or a nano powder, and the carrier agent is at least one of a binder or a solvent that defines a paste with the at least one of the micro powder or the nano powder disposed therein.

Example 28 includes the method of example 27, wherein the processing of the glass core includes implementing a sintering process.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
a glass layer having a through-hole;
a conductive material within the through-hole; and
a porous material between at least a portion of the conductive material and at least a portion of a sidewall of the through-hole.

2. The apparatus of claim 1, wherein the at least the portion of the sidewall includes a first portion adjacent a first end of the through-hole, and the porous material is between the conductive material and at least a second portion of the sidewall adjacent a second end of the through-hole, at least a third portion of the sidewall between the at least the first portion and the at least the second portion, the porous material spaced apart from the at least the third portion.

3. The apparatus of claim 2, wherein the at least the first portion extends a first length along the through-hole, the at least the second portion extends a second length along the through-hole, and the at least the third portion extends a third length along the through-hole, the third length greater than the first length and greater than the second length.

4. The apparatus of claim 3, wherein the first and second lengths are less than 20 micrometers.

5. The apparatus of claim 1, wherein the porous material extends a full length along the sidewall of the through-hole from opposing first and second surfaces of the glass layer.

6. The apparatus of claim 5, wherein the porous material has a first thickness on the sidewall adjacent the first surface and a second thickness on the sidewall adjacent the second surface, the first thickness different from the second thickness.

7. The apparatus of claim 1, wherein the porous material is defined by a plurality of pores within a polymer matrix, and adjacent ones of the pores define an open channel through a thickness of the porous material.

8. The apparatus of claim 1, wherein the glass layer includes a first surface and a second surface opposite the first surface, the through-hole extends between the first and second surfaces, and the porous material extends along at least one of the first surface or the second surface.

9. The apparatus of claim 1, wherein the glass layer includes a first surface and a second surface opposite the first surface, the through-hole extends between the first and second surfaces, the porous material spaced apart from the first and second surfaces.

10. The apparatus of claim 1, wherein the porous material includes at least one of a polymer or a ceramic.

11. The apparatus of claim 1, wherein the porous material includes a metal.

12. An apparatus comprising:
a glass core having a first surface and a second surface opposite the first surface, the glass core including an opening, the opening including a metal extending between the first and second surfaces; and
a material coating an inner surface of the opening between the metal and the inner surface, the material including voids, the voids providing a porosity of at least 10%.

13. The apparatus of claim 12, wherein the material coats less than all of the inner surface of the opening.

14. The apparatus of claim 12, wherein the voids define at least one fluid channel.

15. The apparatus of claim 12, wherein a thickness of the material differs at different depths within the opening.

16. The apparatus of claim 12, wherein the material coats the first surface of the glass core.

17. An apparatus comprising:
a semiconductor die;
a substrate to support the semiconductor die, the substrate including a glass core, the glass core having a through-glass via (TGV) extending therethrough, the TGV including metal electrically coupled to the semiconductor die; and
a porous liner at least partially surrounding an outer sidewall of the metal in the TGV.

18. The apparatus of claim 17, wherein the porous liner completely surrounds the outer sidewall of the metal along a full length of the TGV.

19. The apparatus of claim 17, wherein the porous liner at least partially surrounds opposing ends of the outer sidewall of the metal and is spaced apart from a central segment of the TGV.

20. The apparatus of claim 17, wherein the porous liner has a porosity of at least 25%.

21-28. (canceled)
